(19) United States
(12) Patent Application Publication
(10) Pub. No.: US 2013/0059251 A1
(43) Pub. Date: Mar. 7, 2013

(54) MICRO/NANO PHOTOCONDUCTOR

(71) Applicants: Gurunarayan Govind, Maharashtra (IN); Amalnerkar Pundalik-Dinesh, Maharashtra (IN); Mulik Pitambar Uttamrao, Maharashtra (IN); Gosavi Wamangir-Suresh, Maharashtra (IN)

(72) Inventors: Gurunarayan Govind, Maharashtra (IN); Amalnerkar Pundalik-Dinesh, Maharashtra (IN); Mulik Pitambar Uttamrao, Maharashtra (IN); Gosavi Wamangir-Suresh, Maharashtra (IN)

(21) Appl. No.: 13/698,564

(22) PCT Filed: May 16, 2011
(86) PCT No.: PCT/IN2011/000341

§ 371 Date: Nov. 16, 2012

(30) Foreign Application Priority Data
May 18, 2010 (IN) 1561/MUM/2010

(51) Int. Cl. G03F 7/004; G03F 7/20

(52) U.S. Cl. 430/280.1; 430/270.1; 430/312

(57) ABSTRACT

The present invention discloses a method for fabricating and integrating a micro/nano photoconductor using a photoconductor formulation especially suitable for thick film patterning. The photoconductor formulation comprises: an organic component including a photosensitive polymer and a photoinitiator, and an inorganic component including an activated photoconducting powder comprising cadmium sulfide, copper, and chlorine. The present invention provides low-cost, thick film optical sensors having extremely fine geometries (<100 μm) and high sensitivity.

### FIELD OF INVENTION

The present invention relates to the field of photoconductors.

Particularly, the present invention relates to the field of micro/nano photopatternable photoconductors.

### DEFINITIONS OF TERMS USED IN THE SPECIFICATION

The term “photosensitive polymer” used in the specification means a polymer that responds to ultraviolet or visible light by exhibiting a change in its physical or chemical properties.

The term “photoinitiator” used in the specification means a chemical compound that decomposes into free radicals when exposed to light.

The term “positive photomask” used in the specification means a structure comprising functional opaque pattern images produced on a transparent film, plastic, or glass-based material and accurately positioned so as to provide selective exposure of a photoresist coating to light.

The term “negative photomask” used in the specification means a structure comprising functional transparent pattern images produced on an opaque . film, plastic, or glass-based material and accurately positioned so as to provide selective exposure of a photoresist coating to light.

### BACKGROUND

A photoconductor or a light dependent resistor is a resistor made from a high resistance semiconductor in which the resistance of the resistor decreases with an increase in the incident light intensity. The photoconductivity of the photoconductor is an opto-electrical phenomenon in which the semiconductor material becomes more conductive by absorption of the electromagnetic radiation. The absorption of radiations is a quantum process, which takes place when the semiconductor material absorbs photons having energies greater than or equal to their band gap energy. The process results in excitation of electrons to a higher energy level. This is an important process because significant photoelectric effects are based on the absorption process which occurs in the UV, visible and IR wavelength regimes.

The semiconducting materials used for making the photoconductors are included in the group IV elements (Si, Ge), group III-V compounds (GaN, GaAs, InP) and group II-VI compounds (ZnS, CdS, CdSe). The broad band gaps of these semiconducting materials leads to a wide spectral response ranging from far infrared to ultraviolet light. Depending upon the application of the photoconductor, the semiconductor material and its spectrum can be selected, viz., visible light can be used to take into account the visual effectiveness of the light to the sensitivity response of the human eye (photopic-eye response). Among the compound semiconductors discussed above, cadmium sulfide (CdS) is highly suitable for a visible light photoconductor because of the primary band gap of 2.4 eV (516 nm) at room temperature and high sensitivity. CdS has been widely used in optoelectronics, photonics, and photovoltaics. In opto-electronics, it is used for making photocells, light emitting diode (LED), and lasers. In photonics, CdS is employed to make nanocrystals, optical filters, and optical switches. However, the relatively low response speed of CdS (bulk or films), wherein the response speed is measured by the time taken for the photogenerated signal to rise from 10 to 90% of the dark current and steady-state current on exposure to light or the time taken for the signal to fall from 90 to 10% of the value when the light is turned off, limiting the application of CdS in high frequency and high speed devices, such as light-wave communication or opto-electronic switches.

Referring to FIG. 1, therein is disclosed a conventional cadmium sulfide photoconductor and its operation circuit thereof. The CdS photoconductor is generally referred in FIG. 1 by the numeral 100. The sides of the CdS photoconductor 100, represented by numerals 102 and 104, showing the cross-sectional area of the CdS photoconductor 100, are connected to a set of electrodes 106 and 108, respectively. In the absence of light, the CdS photoconductor 100 has a very high resistance. When a voltage is applied between the electrodes 106 and 108 by using a battery 110, an ammeter. 112 connected in series with the battery 110 shows a small dark current. This small dark current is the characteristic thermal equilibrium current of the CdS photoconductor 100. When light is incident on the CdS photoconductor 100, current flows. In FIG. 1, the sides 102 and 104 of the CdS photoconductor 100 are exposed to a uniform volume excitation in a steady state which generates free electrons at a total rate of “f” per second. The photoconductivity of the CdS photoconductor 100 is directly proportional to the product of mobility and life-time of free carriers and inversely proportional to the square of inter-electrode distance, thus, shorter the distance between the electrodes higher the sensitivity of the CdS photoconductor 100.

Several studies have been carried out to enhance the life-time of the free carriers to increase the photoconductivity of the CdS photoconductor 100, wherein photoconductivity is the variation in conductivity of a semiconductor material under the action of electromagnetic radiations especially light, and practically every semiconductor material should exhibit photoconductivity under suitable illumination. In practice, the life-time of the free carriers is enhanced by either deliberately incorporating special types of sensitizing imperfections in the photoconducting matrix and/or using various deposition techniques such as thick film technology, chemical bath deposition, vapor phase deposition, and the like. However, while enhancing the photoconductivity of the CdS photoconductor 100 by adding impurities and/or by using a different deposition technique, the interelectrode spacing is often ignored. This could be due to the limitations of the conventional techniques used for fabricating the photoconductor pattern with a reduced inter-electrode spacing while providing an improved photoconductor path between the electrodes 106 and 108.

Thick film technology is widely used for selective deposition of photoconducting CdS element in the photoconductor as it is simple, cost-effective and provides high performance efficiencies. However, the thick film technology cannot be used for a line less than 250 μm in manufacturing process. Yet another deposition technique, is the thin film technology which is suitable for patterning less than 250 micron pattern structures, however, reaction with various chemicals, compatibility and pattern damage during the processing are the prime concerns when fabricating a photoconductor using the thin film technology. Therefore, there is need for a deposition technique that overcomes the drawbacks of the conventional techniques.

Photopatterning is defined as the production of a photochemical patterning on the surface of a semiconductor, wherein photopatterning is done to provide a simple, low cost, miniature micro-photoconducting element, which allows selective transfer and accurate registration along with miniaturization of the photoconductor device. Metal-chalcogenides, for one dimensional structures like rods, tubes, wires, and the like, or two dimensional structures like films of compound semiconductors, have been widely explored in various fields of micro-electro-optical systems such as telecommunication, data storage, information display, sensing/optical switches, and the like. Apart from developing novel technology for fabricating and integrating micro-optical systems in electronic devices, there is a growing demand for miniaturization of the conventional electro-optical systems.

Typically, photolithography, electron beam lithography and related methods are used for micro/nano fabrications in micro-electronics and display systems. The aforementioned conventional methods are complex, involve high capital investment and operating costs, are difficult when patterning large areas, and can be applied for direct patterning only a limited range of materials. Additionally, the chemicals such as resist, etchant, developers, solvents, etc., used in the aforementioned methods are incompatible with a wide range of compound semiconductor materials which are can otherwise be suitably advantageous. Therefore, there is a need to provide an advanced patterning technique which overcomes the limitations of the aforementioned conventional methods. Also, there is a need to provide a compound semiconductor material which exhibits enhanced performance characteristics. Further, with the ever advancing miniaturization in the field of semiconductor technology and microelectronics, there is a desperate need to provide micro/nano photoconductors.

### OBJECTS OF THE INVENTION

An object of the present invention is to provide a micro/nano photoconductor.

Another object of the present invention is to provide a patterning technique for fabrication and integration of the micro/nano photoconductor.

Still another object of the present invention is to provide a patterning technique for fabrication and integration of the micro/nano photoconductor which is simple and cost-effective.

Yet another object of the present invention is to provide a patterning technique for fabrication and integration of the micro/nano photoconductor which can be smoothly used over large areas.

One more object of the present invention is to provide a patterning technique for fabrication and integration of the micro/nano photoconductor which can be used for a wide range of semiconducting materials.

Still one more object of the present invention is to provide a patterning technique for fabrication and integration of the micro/nano photoconductor which enhances the workability of the semiconductor material used therein.

Yet one more object of the present invention is to provide a micro/nano photoconductor made from a semiconductor material which uses visible light taking into account the sensitivity response of the human eye (photopic-eye response).

### SUMMARY OF THE INVENTION

In accordance with the present invention, is disclosed a photoconductor formulation for thick film photopatterning, said formulation comprising:
i. an organic component comprising:
   a photosensitive polymer of novalac epoxy resin containing a ∝-substituted monocarboxylic acid with an average epoxy equivalent weight ranging between 70 to 4000; preferably between 130 to 500; and
   a photoinitiator selected from the group of acetophenone derivatives consisting of 1,1-dichlo-acetophenone, 2,2-dimethoxy-2-phenyl acetophenone 2,2-diethoxyacetophenone, p-t-butyl dichloroacetophenone and 2,2-dichloro-4-phenoxyacetophenone ; and
ii. an inorganic component including an activated photoconducting powder comprising :
   at least one semiconductor material selected from the group consisting of cadmium, selenide, lead(II)sulfide, zinc oxide and zinc sulfide; and
   at least one doping agent selected from the group consisting of copper, chloride, silver and indium;

wherein, the ratio of said inorganic component to said organic component in said formulation is in the range of 65-80:35-20.

Typically, in accordance with the present invention, said activated photoconducting powder comprises cadmium sulfide, copper, and chlorine.

Preferably, in accordance with the present invention, said activated photoconducting powder comprises cadmium sulfide (CdS), copper chloride (CuCl₂.2H₂O), and cadmium chloride (CdCl₂.2.5H₂O).

Typically, in accordance with the present invention, copper chloride is present in the range of 0.02-1.0 wt % of the cadmium sulfide in said activated photoconducting powder.

Preferably, in accordance with the present invention, cadmium chloride is present in the range of 6-12 wt % of the cadmium sulfide in said activated photoconducting powder.

In accordance with the present invention, is disclosed a method for preparing a photoconductor formulation for thick film photopatterning, said method comprising the steps of combining an inorganic component comprising photoconducting powder comprising:
at least one semiconductor material selected from the group consisting of cadmium, selenide, lead(II)sulfide , zinc oxide and zinc sulfide; and
at least one doping agent selected from the group consisting of copper, chloride, silver and indium;

with an organic component comprising:
a photosensitive polymer of novalac epoxy resin containing a ∝-substituted monocarboxylic acid with an average epoxy equivalent weight ranging between 70 to 4000; preferably between 130 to 500 and
a photoinitiator selected from the group of acetophenone derivatives consisting of 1,1-dichlo-acetophenone, 2,2-dimethoxy-2-phenyl acetophenone, 2,2-diethoxyacetophenone, p-t-butyl dichloroacetophenone and 2,2-dichloro-4-phenoxyacetophenone;

so as to sufficiently wet said inorganic component to obtain an activated photoconducting paste of the photoconductor formulation for thick film photopatterning, said activated photoconducting paste having said inorganic component to said organic component ratio in the range of 65-80:35-20.

In accordance with the present invention, is disclosed a method for preparing an activated photoconducting powder, said method comprising the steps of:
combining pure cadmium sulfide (CdS) powder with copper chloride (CuCl₂.2H₂O) in the range of 0.02-1.0 wt % of the CdS and cadmium chloride (CdCl₂.2.5H₂O) in the range of 6-12 wt % of the CdS;
mixing the ingredients with acetone in a ball mill for 2-4 hours to obtain a resultant paste;
firing the resultant paste at a temperature in the range of 450-550° C. in the presence of air for 2-4 hours to obtain photoconductive lumps;
powdering the photoconductive lumps with acetone to obtain activated photoconducting powder having particle size in the range of 200 nm to 800 nm.

In accordance with the present invention, is disclosed a method for fabricating and integrating a photoconductor using the activated paste of the photoconductor formulation, said method comprising the steps of:
patterning back electrode, including the steps of:
   screen printing the paste of said conductor formulation on a clean alumina substrate to obtain a printed substrate;
   leveling the printed substrate for 5-20 minutes at a temperature in the range of 18-40° C. to obtain a leveled printed substrate;
   drying the leveled printed substrate in a ventilated oven box for 15-25 minutes at a temperature in the range of 65-85° C. to obtain a first printed green film;
   exposing the first printed green film to UV radiations using a positive interdigited photomask having a structure selected from comb and serpentine;
   developing the unexposed region of the first printed green film by means of a pressure mist of aqueous Na₂CO₃ solution to obtain a printed film having an interdigited pattern; and
   firing the printed film having the interdigited pattern at a temperature in the range of 800-900° C. for 5-15 minutes in the presence of air to obtain a pre-patterned fired conductor film having thickness in the range of 8-10 microns; and
transferring selectively the micro-photoconductive elements, including the steps of:
   screen printing the activated paste of said photoconductor formulation on the pre-patterned fired conductor film to obtain a printed photoconductor film;
   leveling the printed photoconductor film for 5-20 minutes at a temperature in the range of 18-40° C. to obtain a leveled printed photoconductor film;
   drying the leveled printed photoconductor film in a ventilated oven box for 15-25 minutes at a temperature in the range of 65-85° C. to obtain a second printed green film;
   exposing the second printed green film to UV radiations using a negative interdigited photomask having a structure selected from comb and serpentine, wherein, the interdigited pattern of the negative photomask is well aligned with the interdigited pattern of the positive photomask on the pre-patterned fired photoconductor film;
   developing the unexposed region of the second printed green film by means of a pressure mist of aqueous Na₂CO₃ solution to obtain a printed film having micro-photoconductive elements;
   firing the printed film having the micro-photoconductive elements at a temperature in the range of 450-650° C. for 20-40 minutes in the presence of air to obtain the photoconductor.

Typically, in accordance with the present invention, the method for fabricating and integrating a photoconductor includes the step of exposing the first and the second printed green films to UV radiations having wavelength in the range of 365-400 nm using a mercury UV lamp.

In accordance with another aspect of the present invention there is provided a micro photoconductor prepared from the formulation as substantially described herein above.

### BRIEF DESCRIPTION OF THE ACCOMPANYING DRAWINGS

The invention will now be described with reference to the accompanying drawings, in which;

FIG. 1 illustrates a CdS photoconductor and an operation circuit thereof;

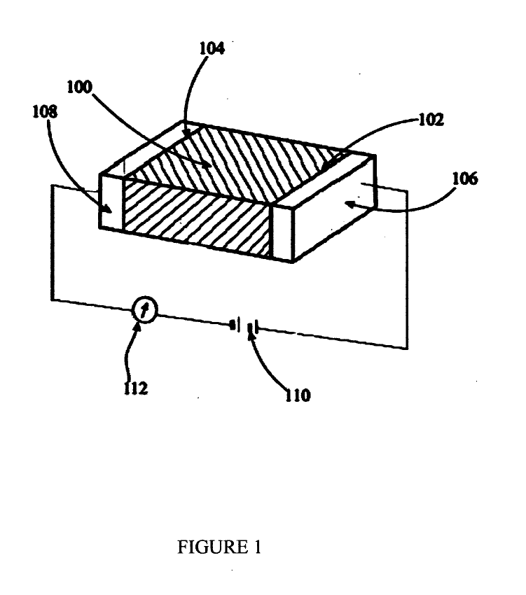

FIG. 2 illustrates a preferred method for preparing an activated photoconducting powder, in accordance with the present invention;

FIG. 3 illustrates a preferred method for the fabrication and integration of the micro/nano photoconductor, in accordance with the present invention;

FIG. 4 illustrates a stereomicroscopic image of the micro/nano photoconductor, in accordance with the present invention;

FIG. 5 illustrates FESEM images of: a) pure CdS powder, b) pure CdS powder preheated at 300° C., c) admixture of CdS powder+CdCl₂+CuCl₂ preheated at 300° C., and d) admixture of CdS powder+CdCl₂+CuCl₂ preheated at 500° C.

FIG. 6 illustrates thermal curves of TG/DTG/DTA (Model—Mettler Toledo 851^{e}) analysis on the photoconductor paste formulation, in accordance with the present invention;

FIG. 7 illustrates current-voltage curves obtained when test samples in accordance with the present invention were exposed to light; and

FIG. 8 illustrates the spectral response curve for the CuCl₂ doped CdS photoconductor of the present invention.

### DETAILED DESCRIPTION OF THE ACCOMPANYING DRAWINGS

The present invention envisages a micro/nano photoconductor and a simple and cost-effective photopatterning technique for fabricating and integrating the photoconductor. The present invention also envisages a photoconductor formulation for thick film photopatterning which is used for fabricating the micro/nano photoconductor. The photopatterning technique in accordance with the present invention can be easily used over a large area and is compatible with a variety of semiconductor materials. Further, the deposition technique of the present invention enhances the performance characteristics of the photoconductor. The micro/nano photoconductor of the present invention preferably uses visible light, to take into account the sensitivity response of a human eye (photopic-eye response). The present invention further aims at providing a technique for thick film photopatterning involving applying and selectively patterning a photoconductive paste on an alumina substrate. This is achieved by: understanding the behavior of the photoconductive paste during processing and firing; and correlating the evolution of the microstructure with electrical properties.

In accordance with a preferred embodiment of the present invention, is provided a photoconductor formulation for thick film photopatterning. The photoconductor formulation is a paste which comprises: an organic component including a photosensitive polymer and a photoinitiator, and an inorganic component including an activated photoconducting powder. Typically, the photosensitive polymer is a novalac epoxy resin containing a ∝-substituted monocarboxylic acid with an average epoxy equivalent weight ranging between 70 to 4000; preferably between 130 to 500. Typically, the photosensitive polymer works as a temporary binder. The photoinitiator used in the photoconductor formulation is selected from the group of acetophenone derivatives consisting of 1,1-dichlo-acetophenone, 2,2-dimethoxy-2-phenyl acetophenone , 2,2-diethoxyacetophenone, p-t-butyl dichloroacetophenone and 2,2-dichloro-4-phenoxyacetophenone. The activated photoconducting powder is the functional material of the photoconductor formulation of the present invention and typically comprises a semiconductor material and a doping agent(impurities). Typically, the semiconductor material is selected from the group consisting of cadmium, selenide, lead(II)sulfide , zinc oxide and zinc sulfide. Typically, the doping agent is at least one selected from the group consisting of copper, chloride, silver and indium. The inorganic and the organic components of the photoconductor formulation are present in a ratio ranging from 65-80:35-20.

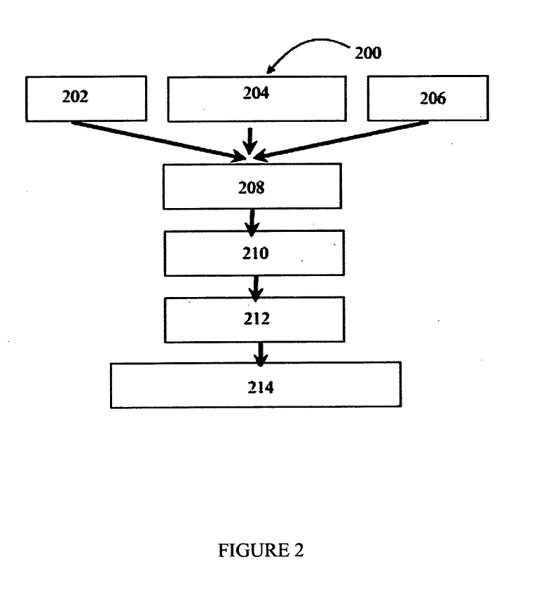

Referring to FIG. 2, therein is illustrated a method for preparing the activated photoconducting powder, comprising CdS, copper and chlorine, for the photoconductor formulation of the present invention. The method is generally represented in FIG. 2 by numeral 200. The activated photoconducting powder is prepared by combining a photoconductive material 204, typically pure cadmium sulfide (CdS) powder, with an activator 202, typically copper chloride (CuCl₂.2H₂O), and a flux material 206, typically cadmium chloride (CdCl₂.2.5H₂O); where, the photoconductive material (CdS) 204 is a major component and the activator 202 (copper chloride) is preferably present in the range of 0.02-1.0 wt % of the CdS and the flux 206 (cadmium chloride) is preferably present in the range of 6-12 wt % of the CdS. In accordance with one of the embodiments of the present invention, the activated photoconducting powder composition is provided in TABLE 1.

TABLE 1
Activated photoconducting powder composition.

| | | | Quantity |
|---|---|---|---|
| Material | Function | Quality | in gms |
| CdS | Basic | 99.99% pure | 100 |
| | Photoconducting | A.R. grade | |
| | Matrix | | |
| CdCl₂•2.5H₂O | Flux Material | A.R. grade | 10 |
| CuCl₂•2H₂O | Activator | A.R. grade | 0.05 |

The ingredients are mixed with acetone in a ball mill for 2-4 hours to obtain a homogenous resultant paste; the process step is represented in FIG. 2 by numeral 208. This resultant paste is bulk fired in the presence of air at a temperature in the range of 450-550° C. for 2-4 hours to obtain photoconductive lumps; the process step is represented in FIG. 2 by numeral 210. The bulk firing helps in incorporation of the activator component in the CdS matrix. Finally, the photoconductive lumps are powdered or pulverized in the process step 212, with or without acetone, to obtain the activated photoconducting powder, which has particle size in the range of 200 nm to 800 nm. This activated photoconducting powder so obtained in the process step 214 is a fine, light brown powder, which forms the inorganic component of the photoconductor formulation, optionally with a glass binder.

To prepare the photoconductor formulation for thick film photopatterning the activated photoconducting powder obtained in process step 214, with or without the glass binder, is admixed with the organic component comprising the photosensitive polymer and the photoinitiator, where, the ratio of the inorganic component to the organic component is maintained in the range of 65-80:35-20, such that the organic component sufficiently wets the inorganic component. The mixture so formed is thoroughly mixed, manually or mechanically, to obtain a consistent uniform paste of the photoconductor formulation. The fluidity of the photoconductor formulation paste is largely dependent on the quantity of the organic component used. In accordance with of the embodiments of the present invention the photoconductor formulation composition is provided in TABLE 2. In accordance with an aspect of the present invention there is provided a micro photoconductor prepared from the formulation as substantially described herein above.

TABLE 2
Photoconductor formulation composition.

| | Photoconductor | Formulation - 1 | Formulation - 2 |
|---|---|---|---|
| | Formulation Paste | (wt %) | (wt %) |
| Organic | Photosensitive | 27.65 | 27.65 |
| Component | Polymer Binder | | |
| | Photoinitiator | 00.37 | 00.37 |
| Inorganic | Functional Material | 66.98 | 71.98 |
| Component | (activated | | |
| | photoconducitng | | |
| | powder) | | |
| | Glass Binder | 05.00 | — |

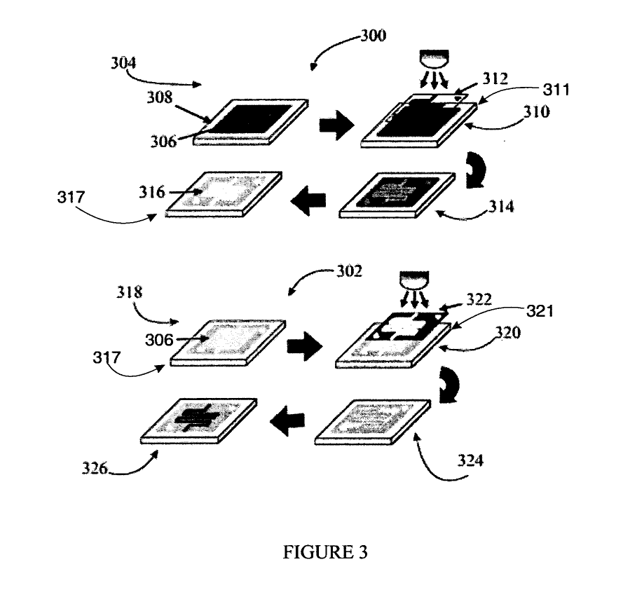

Referring to FIG. 3, therein is disclosed a method for fabricating and integrating the micro/nano photoconductor, in accordance with the present invention. The photoconductor formulation paste comprising the activated photoconducting powder of step 214 is used in the fabrication of the micro/nano photoconductor. The method for fabrication of the photoconductor and integration of the micro-photoconductive sensing elements comprises two steps: back electrode patterning, represented in FIG. 3 by numeral 300, and selective transfer of micro-photoconductive elements, represented in FIG. 3 by numeral 302.

Primarily, a clean alumina substrate 308 is patterned in the back electrode patterning step 300. The clean alumina substrate 308 is liberally screen printed with the conductor formulation paste 306 in the process step 304 to obtain a printed substrate. The process step 304 further comprises leveling the printed substrate for 5-20 minutes, more preferably for 10 minutes, at a temperature in the range of 18-40° C., more preferably in the range of 25-35° C. The leveled printed substrate is dried in a ventilated oven box for 15-25 minutes at a temperature in the range of 65-85° C. The leveling and drying improves the adhesion of the photoconductor formulation 306 on the alumina substrate 308 and helps in removing any traces of solvent from the film so obtained. During the process step 304, it is crucial to minutely monitor the time and temperature so as to prevent any pre-mature cross-linking of the photosensitive system and thereby obtain a first printed green film 311.

In the process step 310, the first printed green film 311 is exposed to UV radiations through a positive interdigited photomask 312; where, the positive photomask 312 typically has a comb or serpentine structure and could have various dimensions. Preferably, a mercury UV lamp having intensity maxima at a wavelength of 365-400 nm is used in the process step 310 to expose the first printed green film 311 to light through the positive photomask 312 by using contact mode. The unexposed region of the printed green film 311 is developed by means of a pressure mist of aqueous Na₂CO₃ solution, in the process step 314, to obtain a printed film having an interdigited pattern. Finally, in the process step 316 of the patterning process 300, the printed film having the interdigited pattern is fired in the presence of air in a four-zone belt furnace at a temperature in the range of 800-900° C. for 5-15 minutes, more preferably for 10 minutes, to obtain a pre-patterned fired photoconductor film 317. The pre-patterned fired film 317 has a thickness in the range of 8-10 microns.

Subsequently, in the process step 302 for the selective transferring of the micro-photoconductive sensing elements, the pre-patterned fired conductor film 317 is liberally screen printed with the photoconductor formulation paste 306, in the process step 318. The printed photoconductor film is then leveled for 5-20 minutes, more preferably for 10 minutes, at a temperature in the range of 18-40° C., more preferably in the range of 25-35° C. The leveled printed photoconductor film is then dried in a ventilated oven box for 15-25 minutes at a temperature in the range of 65-85° C. The leveling and drying improves the adhesion of the photoconductor formulation 306 on the pre-patterned fired photoconductor film 317 and helps in removing any traces of solvent from the film so obtained. During the step 318, it is crucial to minutely monitor the time and temperature to prevent any pre-mature cross-linking of photosensitive system and thereby obtain a second printed green film 321.

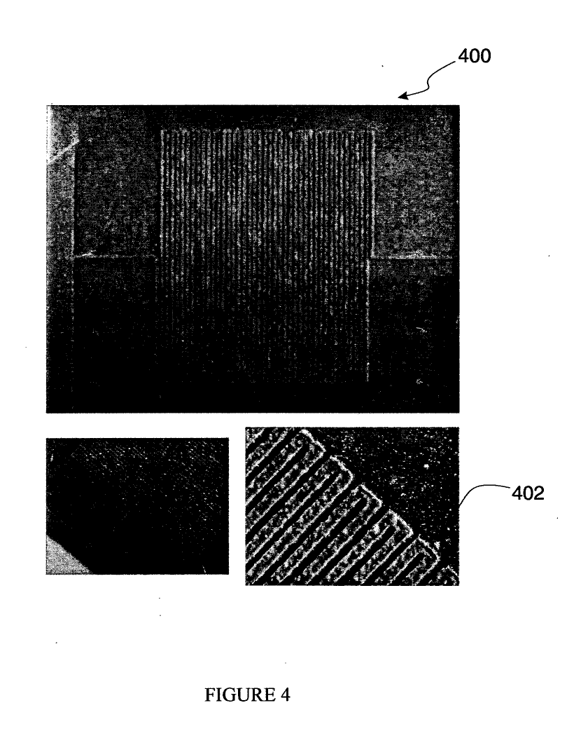

In the process step 320, the second printed green film 321 is exposed to UV radiations through a negative interdigited photomask 322; where, the negative photomask 322 typically has a comb or serpentine structure and could have various dimensions. Preferably, a mercury UV lamp having intensity maxima at a wavelength of 365-400 nm is used in the process step 320 to expose the second printed green film 321 to light through the negative photomask 322 by using contact mode to selectively transfer the micro-photoconductive sensing elements. The interdigited pattern of the negative photomask 322 is well aligned with the interdigited pattern of the positive photomask 312 on the pre-patterned fired photoconductor film 317. The unexposed region of the printed green film 321 is developed by means of a pressure mist of aqueous Na₂CO₃ solution, in the process step 324, to obtain a printed film having micro-photoconductive elements. In the final step 326, the printed film having the micro-photoconductive elements is fired in the presence of air in a four-zone belt furnace at a temperature in the range of 450-650° C. for 20-40 minutes, more preferably for 30 minutes, to obtain the micro/nano photoconductor of the present invention. FIG. 4 illustrates a stereomicroscopic image of the photoconductor of the present invention having an interelectro spacing of 100 μm; represented in FIG. 4 by numeral 400. A zoomed image 402 of the photoconductor 400 shows the selective transfer and accurate registration of the micro-photoconductive elements.

### Test Results

The invention will now be described with respect to the following examples and illustrations which do not limit the scope and ambit of the invention in anyway and only exemplify the invention.

Six test samples of the photoconductor of the present invention were fabricated, each with a different geometric, i.e., gap/spacing in microns. The geometrics of the test samples are listed in TABLE 3.

TABLE 3
Geometrics of the test samples used.

| | |
|---|---|
| Sr. | Geometries (gap/spacing, μ) |

| no. | Length = 12 mm | Length = 50 mm |
|---|---|---|
| 1 | A: CdS gap 100 - | D: CdS gap 100 - |
| | Electrode gap 100 | Electrode gap 100 |
| 2 | B: CdS gap 100 - | E: CdS gap 100 - |
| | Electrode gap 200 | Electrode gap 200 |
| 3 | C: CdS gap 100 - | F: CdS gap 200 - |
| | Electrode gap 300 | Electrode gap 100 |

### Grain Size Analysis of the Activated Photoconducting Powder:

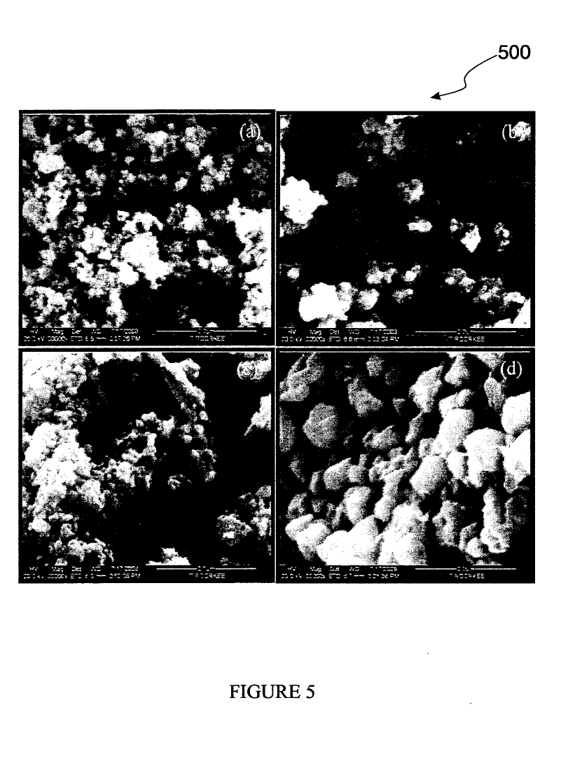

FIG. 5 illustrates Field-emission Scanning Electron Microscopy (FESEM) images of: a) pure CdS powder, b) pure CdS powder preheated at 300° C., c) admixture of CdS powder+CdCl₂ (10%)+CuCl₂ (0.05%) preheated at 300° C., and d) admixture of CdS powder+CdCl₂ (10%)+CuCl₂ (0.05%) preheated at 500° C., generally represented in FIG. 5 by numeral 500. The images highlight the dependence of structural phase transformation on CdCl₂ (flux) assisted CuCl₂ doping process. FIG. 5 (a) & (b) do not show any noticeable change in the morphological features (agglomerated spherical particles). FESEM images FIG. 5 (c) & (d) correspond to CdCl₂ (flux) assisted CuCl₂ doping of CdS powder at two different temperatures viz., 300° C. and 500° C. for a duration of 1 hour. It was observed that as a result of the thermal treatment involved in the CuCl₂ doping process of pure CdS powder, hexagonal facets were formulated, more specifically at a temperature of 500° C. (refer FIG. 5(d)).

### Thermal Stability of the Photoconductor Paste Formulation:

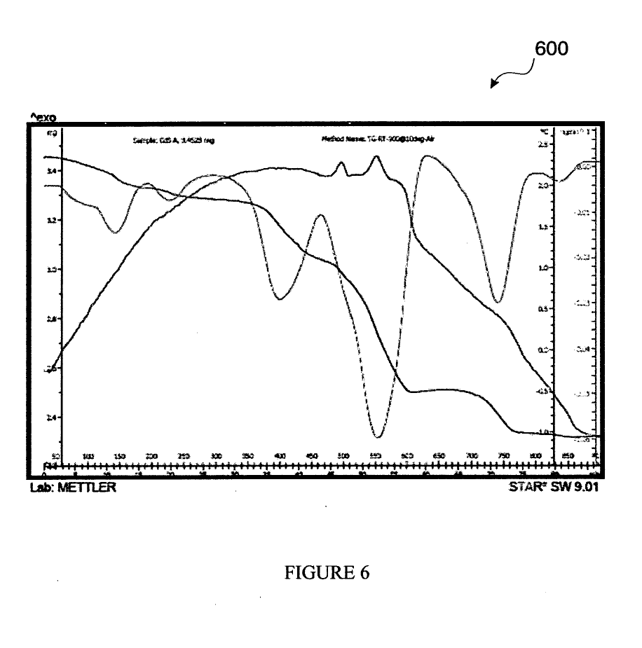

FIG. 6 illustrates thermal curves of the TG/DTG/DTA (Model—Mettler Toledo 851^{e}) analysis performed on the photoconductor paste formulation of the present invention to understand the thermal behavior and stability of the paste composition. The TG analysis, represented by numeral 600 in FIG. 6, indicates: (i) first weight loss at around 150° C., which corresponds to the evaporation of the solvent in the polymer binder; (ii) second weight loss happens between 400° C. to 550° C. (total 24%), which corresponds to the combined effect of burn-out of the polymer and melting and subsequent evaporation of flux (CdCl₂); (iii) remaining weight loss (73%) implies the presence of only activated CdS mass with traces of carbon residue. This thermal behavior suggests that the process of CdCl₂ assisted recrystallization starts at a temperature below the melting point of CdCl₂ (568° C.). This thermo-gravimetric trend was in conformity with the FESEM observations in FIG. 5; where, the hexagonal faceted growth of CdS starts at approximately 300° C. and completes at approximately 500° C. during the CuCl₂ doping process.

### Photoconductivity Measurements

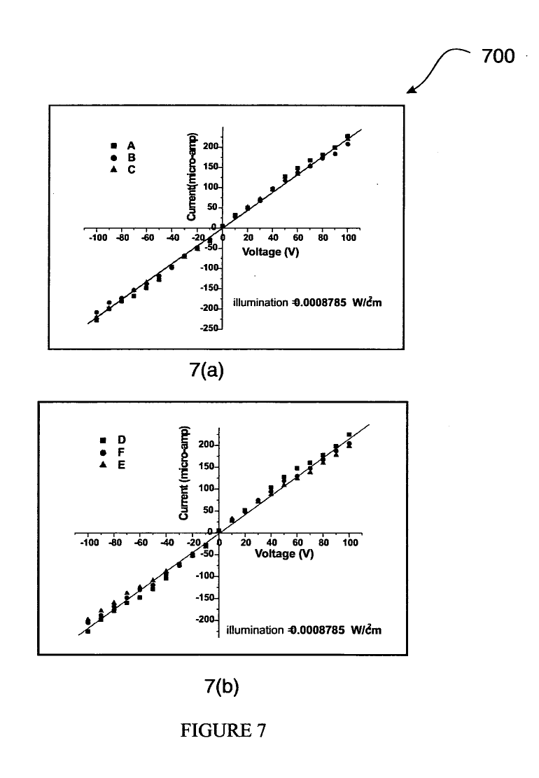

The photoconducting properties were measured in a Thermally Insulated and Shielded dark box with lid (sample holder) using Keithley Electrometer Amplifier (Model-2010), Digital Storage Oscilloscope (Yokogawa, Model—DL 1520), Lux meter (Model—Mextech LX1010B), Tungsten Light Source operated at 2500° K and Neutral Density Filters (New England Nuclear, DuPont), mounted together on an optical bench to produce various levels of illumination. FIG. 7 (a) & (b) illustrate typical current(I)-voltage(V) curves obtained when test samples A, B, C, D, E, & F, having different geometrics, were exposed to light at a constant intensity of 0.0008785 W/cm2 (˜6000 Lux) with the bias ranging from −100 V to 100 V. The nearly linear shape of the curves (refer FIG. 7) implies good ohmic contact of the photoimageable Ag electrode with the photoconductor element of the present invention.

### Photosensitivity & Capacitance Data

The photosensitivity data indicates the efficiency of the photoconductor of the present invention in converting photon flux into an electrical current. TABLE 4 summarizes the photosensitivity data for the test samples A, B, C, D, E, & F.

TABLE 4
Photosensitivity data of the test samples.

| | | Light | Dark | |
|---|---|---|---|---|
| Sr. | | resistance | resistance | Photosensitivity |
| no. | Samples | (Ohm Rᵢ) | (Ohm R_{d}) | (S = (R_{d} − Rᵢ)/Rᵢ) |
| | Length 12 mm | | | |
| 1 | A | 660 × 10³ | 5.33 × 10⁸ | 8.07 × 10² |
| 2 | B | 1140 × 10³ | 4.506 × 10⁸ | 3.94 × 10² |
| 3 | C | 1500 × 10³ | 3.09 × 10⁸ | 2.06 × 10² |
| | Length 50 mm | | | |
| 1 | D | 2140 × 10³ | 2.191 × 10⁹ | 1.02 × 10³ |
| 2 | E | 6200 × 10³ | 1.59 × 10⁹ | 2.56 × 10² |
| 3 | F | 4450 × 10³ | 2.54 × 10⁹ | 5.70 × 10² |

TABLE 5 summarizes the geometrical characteristics and the capacitance data for the photoconductor of the present invention.

TABLE 5
Capacitance data of the test samples.

| | Interdigital Gap | | | | | |
|---|---|---|---|---|---|---|
| | Sample Number | | | | | |
| | A | B | C | D | E | F |
| Gap | 100 | 100 | 100 | 100 | 100 | 200 |
| length, | | | | | | |
| L (μm) | | | | | | |
| Finger | 100 | 200 | 300 | 100 | 200 | 100 |
| Width, | | | | | | |
| l (μm) | | | | | | |
| Electrode | 12 | 12 | 12 | 50 | 50 | 50 |
| effective | | | | | | |
| Width, | | | | | | |
| Nd (mm) | | | | | | |
| Measured | 1.75 | 0.710 | 0.250 | 2.84 | 2.356 | 3.51 |
| capac- | | | | | | |
| itance, | | | | | | |
| C_{D} (pf) | | | | | | |
| Calculated | 0.557 | 0.4734 | 0.3289 | 2.35 | 1.987 | 2.718 |
| Capac- | | | | | | |
| itance, | | | | | | |
| C_{D} (pf) | | | | | | |

### Spectral Response Data

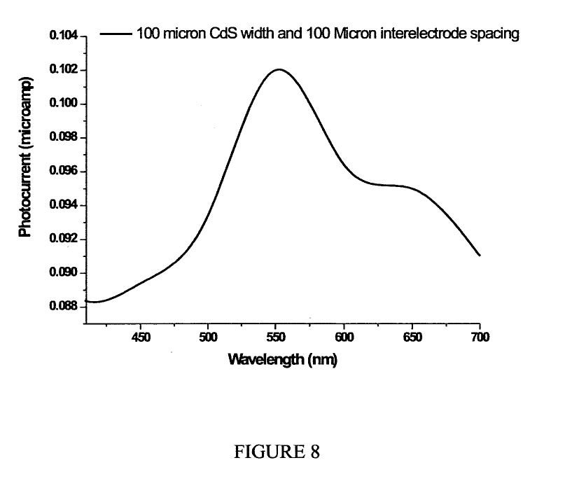

FIG. 8 illustrates the spectral response curve for the CuCl₂ doped CdS photoconductor of the present invention. A monochromatic light was illuminated on the photoconductor device using neutral density filters. The constant bias voltage (10 V) and normalized intensity of illumination (33 lux) was applied to sample. It was observed from spectral response curve that the sample starts responding to light at approximately 450 nm and reaches the peak at approximately 550 nm, which corresponds to the effective band gap of CdS with maximum number of states. Due to the impurity incorporation (doping), there is a shoulder-like peak at approximately 650 nm in the spectral response as seen in FIG. 8.

### Technical Advantages

A micro/nano photoconductor and a patterning technique thereof, in accordance with the present invention has several technical advantages including but not limited to the realization of:
a patterning technique for fabrication and integration of the micro/nano photoconductor which is simple and cost-effective;
a patterning technique for fabrication and integration of the micro/nano photoconductor which can be smoothly used over large areas;
a patterning technique for fabrication and integration of the micro/nano photoconductor which can be used for a wide range of semiconducting materials;
a patterning technique for fabrication and integration of the micro/nano photoconductor which enhances the workability of the semiconductor material used therein;
a micro/nano photoconductor made from a semiconductor material which uses visible light taking into account the sensitivity response of the human eye (photopic-eye response);
a patterning technique that provides a thick film optical sensor with extremely fine geometries (<100 μm) and high sensitivity, at low cost.
the method in accordance with the present invention employs very minimal amount of cadmium sulfide in comparison to the amount required for preparation of conventional photoconductors. This is basically because of nano or micron size of the photoconductor prepared in accordance with the method of the present invention. The reduced use cadmium sulfide in the photoconductor without compromising on its performance renders it eco-friendly and economical.

The numerical values mentioned for the various physical parameters, dimensions or quantities are only approximations and it is envisaged that the values higher/lower than the numerical values assigned to the parameters, dimensions or quantities fall within the scope of the invention, unless there is a statement in the specification specific to the contrary.

In view of the wide variety of embodiments to which the principles of the present invention can be applied, it should be understood that the illustrated embodiments are exemplary only. While considerable emphasis has been placed herein on the particular features of this invention, it will be appreciated that various modifications can be made, and that many changes can be made in the preferred embodiments without departing from the principle of the invention. These and other modifications in the nature of the invention or the preferred embodiments will be apparent to those skilled in the art from the disclosure herein, whereby it is to be distinctly understood that the foregoing descriptive matter is to be interpreted merely as illustrative of the invention and not as a limitation.

1. A photoconductor formulation for thick film photopatterning, said formulation comprising:
i. an organic component comprising:
a photosensitive polymer of novalac epoxy resin containing a ∝-substituted monocarboxylic acid with an average epoxy equivalent weight ranging between 70 to 4000; preferably between 130 to 500; and
a photoinitiator selected from the group of acetophenone derivatives consisting of 1,1-dichlo-acetophenone, 2,2-dimethoxy-2-phenyl acetophenone, 2,2-diethoxyacetophenone, p-t-butyl dichloroacetophenone and 2,2-dichloro-4-phenoxyacetophenone; and
ii. an inorganic component including an activated photoconducting powder comprising :
at least one semiconductor material selected from the group consisting of cadmium, selenide, lead(II)sulfide, zinc oxide and zinc sulfide; and
at least one doping agent selected from the group consisting of copper, chloride, silver and indium;
wherein, the ratio of said inorganic component to said organic component in said formulation is in the range of 65-80:35-20.

2. The photoconductor formulation as claimed in claim 1, wherein said activated photoconducting powder comprises cadmium sulfide, copper and chlorine.

3. The photoconductor formulation as claimed in claim 2, wherein said activated photoconducting powder comprises cadmium sulfide (CdS), copper chloride (CuCl₂.2H₂O), and cadmium chloride (CdCl₂.2.5H₂O).

4. The photoconductor formulation as claimed in claim 3, wherein copper chloride is present in the range of 0.02-1.0 wt % of the cadmium sulfide in said activated photoconducting powder.

5. The photoconductor formulation as claimed in claim 3, wherein cadmium chloride is present in the range of 6-12 wt % of the cadmium sulfide in said activated photoconducting powder.

6. A method for preparing a photoconductor formulation for thick film photopatterning; said method comprising the steps of combining an inorganic component comprising photoconducting powder comprising:
at least one semiconductor material selected from the group consisting of cadmium, selenide, lead(II)sulfide , zinc oxide and zinc sulfide; and
at least one doping agent selected from the group consisting of copper, chloride, silver and indium;
with an organic component comprising:
a photosensitive polymer of novalac epoxy resin containing a ∝-substituted monocarboxylic acid with an average epoxy equivalent weight ranging between 70 to 4000, preferably between 130 to 500; and
a photoinitiator selected from the group of acetophenone derivatives consisting of 1,1-dichlo-acetophenone, 2,2-dimethoxy-2-phenyl acetophenone, 2,2-diethoxyacetophenone, p-t-butyl dichloroacetophenone and 2,2-dichloro-4-phenoxyacetophenone;
so as to sufficiently wet said inorganic component to obtain an activated photoconducting paste of the photoconductor formulation for thick film photopatterning, said activated photoconducting paste having said inorganic component to said organic component ratio in the range of 65-80:35-20.

7. A method for preparing an activated photoconducting powder, said method comprising the steps of:
combining pure cadmium sulfide (CdS) powder with copper chloride (CuCl₂.2H₂O) in the range of 0.02-1.0 wt % of the CdS and cadmium chloride (CdCl₂.2.5H₂O) in the range of 6-12 wt % of the CdS;
mixing the ingredients with acetone in a ball mill for 2-4 hours to obtain a resultant paste;
firing the resultant paste at a temperature in the range of 450-550° C. in the presence of air for 2-4 hours to obtain photoconductive lumps;
powdering the photoconductive lumps with acetone to obtain activated photoconducting powder having particle size in the range of 200-800 nm.

8. A method for fabricating and integrating a photoconductor using the activated paste of the photoconductor formulation as claimed in claim 6, said method comprising the steps of
patterning back electrode, including the steps of:
screen printing the activated paste of said conductor formulation on a clean alumina substrate to obtain a printed substrate;
leveling the printed substrate for 5-20 minutes at a temperature in the range of 18-40° C. to obtain a leveled printed substrate;
drying the leveled printed substrate in a ventilated oven box for 15-25 minutes at a temperature in the range of 65-85° C. to obtain a first printed green film;
exposing the first printed green film to UV radiations using a positive interdigited photomask having a structure selected from comb and serpentine;
developing the unexposed region of the first printed green film by means of a pressure mist of aqueous Na₂CO₃ solution to obtain a printed film having an interdigited pattern; and
firing the printed film having the interdigited pattern at a temperature in the range of 800-900° C. for 5-15 minutes in the presence of air to obtain a pre-patterned fired conductor film having thickness in the range of 8-10 microns; and
transferring selectively the micro-photoconductive elements, including the steps of:
screen printing the activated paste of said photoconductor formulation on the pre-patterned fired conductor film to obtain a printed photoconductor film;
leveling the printed photoconductor film for 5-20 minutes at a temperature in the range of 18-40° C. to obtain a leveled printed photoconductor film;
drying the leveled printed photoconductor film in a ventilated oven box for 15-25 minutes at a temperature in the range of 65-85° C. to obtain a second printed green film;
exposing the second printed green film to UV radiations using a negative interdigited photomask having a structure selected from comb and serpentine, wherein, the interdigited pattern of the negative photomask is well aligned with the interdigited pattern of the positive photomask on the pre-patterned fired photoconductor film;
developing the unexposed region of the second printed green film by means of a pressure mist of aqueous Na₂CO₃ solution to obtain a printed film having micro-photoconductive elements;
firing the printed film having the micro-photoconductive elements at a temperature in the range of 450-650° C. for 20-40 minutes in the presence of air to obtain the photoconductor.

9. The method as claimed in claim 8, which includes the step of exposing the first and the second printed green films to UV radiations having wavelength in the range of 365-400 nm using a mercury UV lamp.

10. A micro photoconductor prepared from the formulation as claimed in claim 1.
